(19) United States
(12) Patent Application Publication
(10) Pub. No.: US 2026/0082709 A1
(43) Pub. Date: Mar. 19, 2026

(54) SENSOR PACKAGE STRUCTURE

(71) Applicants: LITE-ON SINGAPORE PTE. LTD., Singapore (SG); LITE-ON TECHNOLOGY CORPORATION, TAIPEI CITY (TW)

(72) Inventors: WEN-WEN YII, Singapore (SG); JUN-HUA HE, Singapore (SG); WEI JIAN JENSON NEO, Singapore (SG); I-CHEN CHIEN, Keelung City (TW)

(21) Appl. No.: 19/211,313

(22) Filed: May 19, 2025

(30) Foreign Application Priority Data
Sep. 13, 2024 (SG) 10202402862T
Jan. 7, 2025 (CN) 202510021814.1

(51) Int. Cl. H10F 30/10; H10F 77/40; H10F 77/50; H10N 10/81

(52) U.S. Cl. CPC H10F 30/10; H10F 77/407; H10F 77/50; H10N 10/81

(57) ABSTRACT

A sensor package structure includes a substrate, a carrier, a sensing layer, a cap, and an encapsulant that are stacked in sequence. The carrier has a carrying surface and a first slot that is recessed in the carrying surface. The sensing layer is disposed on the carrying surface, and the sensing layer has a plurality of hot junctions spaced apart from each other and a plurality of cold junctions that are spaced apart from each other. The hot junctions are arranged above the first slot, and the cold junctions are arranged above the carrying surface. The cap and the carrier jointly define an enclosed space that receives the sensing layer therein. The cap and the carrier are embedded in the encapsulant, and at least part of the cap corresponding in position to the hot junctions is exposed from the encapsulant.

### CROSS-REFERENCE TO RELATED PATENT APPLICATION

This application claims the benefit of priority to Patent Application No. 202510021814.1, filed on Jan. 7, 2025, in the People's Republic of China. The entire content of the above identified application is incorporated herein by reference.

This application claims the benefit of priority to the Singapore Provisional Patent Application Ser. No. 10202402862T, filed on Sep. 13, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure.

### BACKGROUND OF THE DISCLOSURE

A sensing layer of a conventional sensor package structure is configured to implement a sensing process through hot junctions and cold junctions thereof. However, the cold junctions are easily affected by an external environment (e.g., the cold junctions absorbing a radiant heat or being affected by thermal convection), thereby reducing an accuracy of the sensing process.

### SUMMARY OF THE DISCLOSURE

In response to the above-referenced technical inadequacies, the present disclosure provides a sensor package structure for effectively improving on the issues associated with conventional sensor package structures.

In order to solve the above-mentioned problems, one of the technical aspects adopted by the present disclosure is to provide a sensor package structure, which includes a substrate, a carrier, a sensing layer, a cap, and an encapsulant. The carrier is disposed on the substrate. The carrier has a carrying surface and a first slot that is recessed in the carrying surface. The sensing layer is configured to sense light in a predetermined wavelength and is disposed on the carrying surface of the carrier. The sensing layer has a plurality of hot junctions spaced apart from each other and a plurality of cold junctions that are spaced apart from each other. The hot junctions are located above the first slot, and the cold junctions are located above the carrying surface. The cap is disposed on the carrier to jointly define an enclosed space receiving the sensing layer therein. The encapsulant is formed on the substrate. The carrier and the cap are embedded in the encapsulant, and at least part of the cap corresponding in position to the hot junctions is exposed from the encapsulant.

In order to solve the above-mentioned problems, another one of the technical aspects adopted by the present disclosure is to provide a sensor package structure, which includes a substrate, a processor, a sensing layer, a cap, and an encapsulant. The processor is disposed on the substrate. The processor has a carrying surface and a first slot that is recessed in the carrying surface. The sensing layer is configured to sense light in a predetermined wavelength. The sensing layer is disposed on the carrying surface of the processor and is electrically coupled to the processor. The sensing layer has a plurality of hot junctions spaced apart from each other and a plurality of cold junctions that are spaced apart from each other. The hot junctions are located above the first slot, and the cold junctions are located above the carrying surface. The cap is disposed on the carrier to jointly define an enclosed space receiving the sensing layer therein. The cap has a light-filtering portion and a second slot. The light-filtering portion is arranged above the hot junctions and is configured to allow the light to pass therethrough. The second slot is recessed from a portion of an inner surface of the cap adjacent to the hot junctions toward the light-filtering portion. The encapsulant is formed on the substrate. The processor and the cap are embedded in the encapsulant, and at least part of an outer surface of the light-filtering portion of the cap is exposed from the encapsulant.

Therefore, in the sensor package structure provided by the present disclosure, the sensing layer is enclosed in the carrier and the cap (or the sensing layer is enclosed in the processor and the cap), and then the encapsulant is formed for establishing a dual-package configuration, thereby effectively preventing the sensing layer from being affected by an external environment.

Moreover, since the sensing layer of the sensor package structure provided by the present disclosure is enclosed in the carrier and the cap (or is enclosed in the processor and the cap), the sensing layer can be effectively isolated from the external environment, thereby reducing a heat conduction effect that may possibly affect the hot junctions and increasing the detection accuracy of the sensor package structure.

In addition, in the sensor package structure provided by the present disclosure, the sensing layer can be in cooperation with the internal structures of the carrier and the cap (or the internal structures of the processor and the cap) for reducing heat radiation and convection generated from the hot junctions to affect the cold junctions, thereby effectively increasing the detection accuracy of the sensor package structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to a first embodiment of the present disclosure;

FIG. 2 is a schematic exploded view of FIG. 1;

FIG. 3 is a schematic top view of FIG. 1 with a cap and an encapsulant being omitted;

FIG. 4 is a schematic cross-sectional view taken along line IV-IV of FIG. 1;

FIG. 5 is a schematic perspective view of the sensor package structure according to a second embodiment of the present disclosure;

FIG. 6 is a schematic exploded view of FIG. 5;

FIG. 7 is a schematic top view of FIG. 5 with the cap and the encapsulant being omitted;

FIG. 8 is a schematic cross-sectional view taken along line VIII-VIII of FIG. 5;

FIG. 9 is a schematic perspective view of the sensor package structure according to a third embodiment of the present disclosure;

FIG. 10 is a schematic exploded view of FIG. 9;

FIG. 11 is a schematic top view of FIG. 9 with the cap and the encapsulant being omitted; and

FIG. 12 is a schematic cross-sectional view taken along line XII-XII of FIG. 9.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

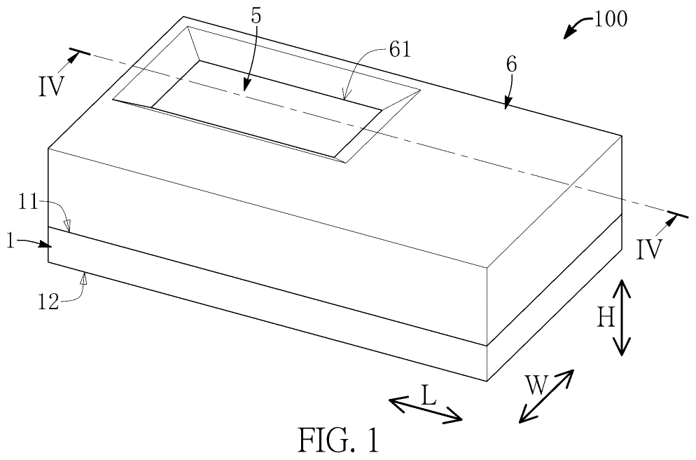

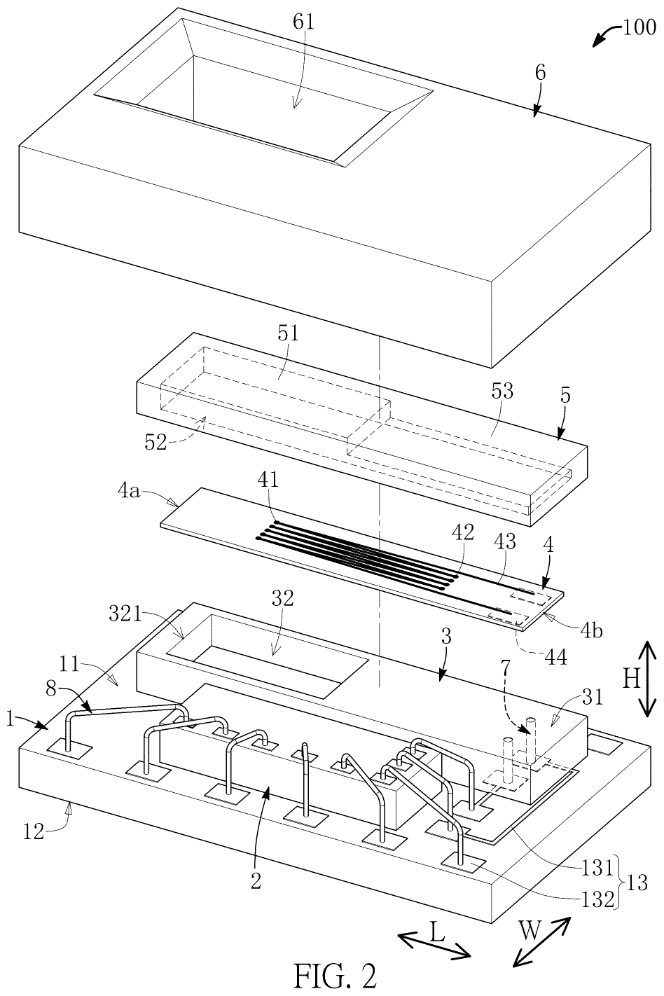

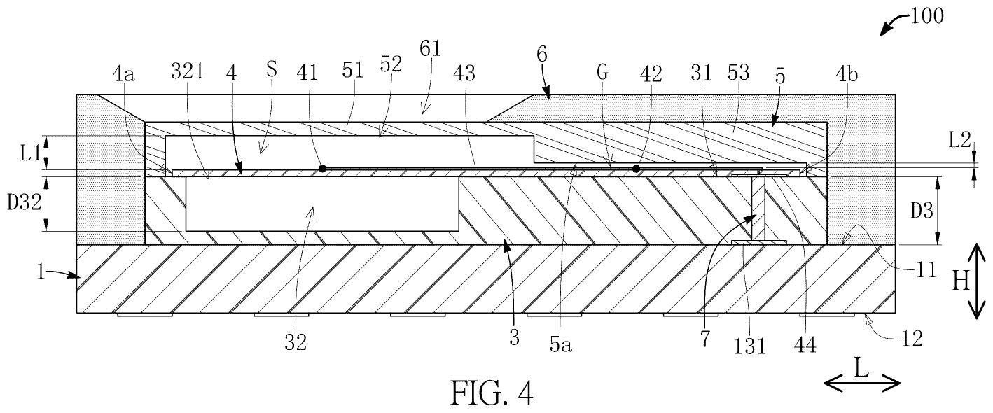

Referring to FIG. 1 to FIG. 4, a first embodiment of the present disclosure provides a sensor package structure 100, which includes a substrate 1, a processor 2 disposed on the substrate 1, a carrier 3 disposed on the substrate 1 and spaced apart from the processor 2, a sensing layer 4 disposed on the carrier 3, a cap 5 disposed on the carrier 3, and an encapsulant 6 that is formed on the substrate 1, but the present disclosure is not limited thereto. For example, in other embodiments of the present disclosure not shown in the drawings, the processor 2 can be omitted or can be replaced by other components according to practical requirements.

In the present embodiment, the substrate 1 is a rectangular board and has a first surface 11 and a second surface 12 that is opposite to the first surface 11, and the substrate 1 further has a circuit layer 13. The circuit layer 13 includes at least one connection circuit 131 arranged on the first surface 11 and a plurality of external circuits 132 that penetrate through the substrate 1.

The processor 2 is disposed on the first surface 11 of the substrate 1 and is electrically coupled to the circuit layer 13. In the present embodiment, the processor 2 is an Application-Specific Integrated Circuit (ASIC) chip, and the processor 2 is electrically coupled to the at least one connection circuit 131 and the external circuits 132 in a wire-bonding manner through a plurality of metal wires 8, but the present disclosure is not limited thereto. For example, in other embodiments of the present disclosure not shown in the drawings, the processor 2 can be electrically coupled to the circuit layer 13 in a flip-chip manner according to practical requirements.

The carrier 3 is disposed on the first surface 11 of the substrate 1 and is arranged adjacent to the processor 2, and the carrier 3 has a carrying surface 31 arranged away from the substrate 1. Specifically, the carrier 3 has a first slot 32 recessed in the carrying surface 31. The first slot 32 preferably does not penetrate through the carrier 3. For example, a depth D32 of the first slot 32 can be within a range from 50% to 90% of a thickness D3 of the carrier 3, but the present disclosure is not limited thereto.

The sensing layer 4 has a plurality of hot junctions 41 spaced apart from each other, a plurality of cold junctions 42 spaced apart from each other, and a thermopile circuit 43 that connects the hot junctions 41 and the cold junctions 42. In other words, the hot junctions 41 and the cold junctions 42 provided by the present embodiment are connected to each other through the thermopile circuit 43. Specifically, along the thermopile circuit 43, any one of the hot junctions 41 is located between two of the cold junctions 42 adjacent to each other.

It should be noted that a specific configuration of the sensing layer 4 can be adjusted or changed according to practical requirements, and in order to clearly disclose the present embodiment, the following description describes one possible configuration of the sensing layer 4, but the present disclosure is not limited thereto. In the present embodiment, the sensing layer 4 is elongated and has a first end 4a and a second end 4b that is opposite to the first end 4a along a longitudinal direction L thereof. The hot junctions 41 are arranged adjacent to the first end 4a of the sensing layer 4, and the cold junctions 42 are arranged adjacent to the second end 4b of the sensing layer 4.

Specifically, the sensing layer 4 defines a width direction W perpendicular to the longitudinal direction L, the hot junctions 41 are arranged along a first layout path P1 parallel to the width direction W, and the cold junctions 42 are arranged along a second layout path P2 parallel to the width direction W. Furthermore, the thermopile circuit 43 has two connection pads 44 that are arranged adjacent to the second layout path P2, and the two connection pads 44 are respectively connected to two of the hot junctions 41 that are arranged on ends (or two end segments) of the thermopile circuit 43. In other words, the two connection pads 44 are arranged adjacent to the second end 4b and are respectively located at two corners of the sensing layer 4.

In the present embodiment, the sensing layer 4 is disposed on the carrying surface 31 of the carrier 3 and is electrically coupled to the processor 2, and a contour of the sensing layer 4 does not protrude from the carrying surface 31. At least 90% of an area of an opening 321 of the first slot 32 is covered or shielded by the sensing layer 4, the hot junctions 41 are located above the first slot 32, and the cold junctions 42 are disposed on the carrying surface 31.

Moreover, an electrical connection between the sensing layer 4 and the processor 2 in the present embodiment can be established by the following structure, but the present disclosure is not limited thereto. The sensor package structure 100 further includes at least one conductive pillar 7 that is embedded in the carrier 3 and that is connected to the circuit layer 13 and the sensing layer 4.

Specifically, a quantity of the at least one conductive pillar 7 embedded in the carrier 3 provided by the present embodiment is two. Bottom ends of the two conductive pillars 7 are connected to the circuit layer 13 (e.g., the at least one connection circuit 131), and top ends of the two conductive pillars 7 are respectively connected to the two connection pads 44, thereby establishing the electrical connection between the sensing layer 4 and the processor 2.

The cap 5 is disposed on the carrying surface 31 of the carrier 3 to jointly define (or form) an enclosed space S receiving the sensing layer 4 therein. In the present embodiment, a peripheral portion of a bottom of the cap 5 is gaplessly connected to a peripheral portion of the carrying surface 31 of the carrier 3, and the cap 5 is not in contact with the sensing layer 4. It should be noted that the opening 321 of the first slot 32 in the present embodiment can have a portion that is not covered (or not shielded) by the sensing layer 4, such that the first slot 32 can be in spatial communication with a second slot 52 of the cap 5 (described in the following description), but the present disclosure is not limited thereto. For example, in other embodiments of the present disclosure not shown in the drawings, the cap 5 can only cover or shield a sensing region defined by the hot junctions 41 and the cold junctions 42 of the sensing layer 4; in other words, the cap 5 is in contact with an outer region (or a non-sensing region) of the sensing layer 4.

Specifically, the cap 5 in the present embodiment has a light-filtering portion 51, a second slot 52, and a separation portion 53 that is arranged at one side of the light-filtering portion 51 and the second slot 52. The light-filtering portion 51 is arranged above the hot junctions 41, and the second slot 52 is recessed from a portion of an inner surface 5a of the cap 5 adjacent to the hot junctions 41 toward the light-filtering portion 51. In other words, the light-filtering portion 51 is at a slot bottom of the second slot 52.

Moreover, along a height direction H perpendicular to the longitudinal direction L and the width direction W, a distance L1 between the light-filtering portion 51 of the cap 5 and any one of the hot junctions 41 is greater than a distance L2 between the separation portion 53 of the cap 5 and any one of the cold junctions 42. In other words, the inner surface 5a (or the separation portion 53) of the cap 5 is arranged adjacent to the cold junctions 42 and is spaced apart from the cold junctions 42 along the height direction H by a gap G that has the distance L2 within a range from 50 μm to 200 μm. A main function of the separation portion 53 is provided to cover or shield a region where the cold junctions 42 are arranged, thereby reducing heat energy being directly transmitted to the cold junctions 42 and preventing a temperature detection of each of the cold junctions 42 from being affected by the hot junctions 41. Accordingly, a significant temperature difference between the cold junctions 42 and the hot junctions 41 can be maintained or provided for increasing detection accuracy of the sensor package structure 100.

In other embodiments of the present disclosure not shown in the drawings, (an opening end of) the second slot 52 can be coplanar with the inner surface 5a (i.e., the second slot 52 being formed or extending to be located above the cold junctions 42).

In addition, the sensing layer 4 is configured to sense light in a predetermined wavelength, and the light-filtering portion 51 of the cap 5 is configured to allow the light to pass therethrough. In the present embodiment, the light sensed by the sensing layer 4 is an infrared radiation, the carrier 3 and the cap 5 are configured to allow the infrared radiation to pass therethrough, and the carrier 3 and the cap 5 are configured to not allow visible light to pass therethrough.

Specifically, the carrier 3 and the cap 5 in the present embodiment are made of silicon, and the transmittance of the infrared radiation of the carrier 3 is preferably less than or equal to the transmittance of the infrared radiation of the cap 5, but the present disclosure is not limited thereto.

It should be noted that the carrier 3, the cap 5, and the sensing layer 4 in the present embodiment can be manufactured in a micro electro mechanical systems (MEMS) manner, thereby effectively meeting precision requirements in the cooperation of the above components.

The encapsulant 6 is formed on the first surface 11 of the substrate 1. The processor 2, the carrier 3, the cap 5, and the metal wires 8 are embedded in the encapsulant 6, and at least part of the cap 5 (e.g., the light-filtering portion 51) corresponding in position to the hot junctions 41 is exposed from the encapsulant 6. In other words, the encapsulant 6 has an opening 61, and the light-filtering portion 51 is exposed from the encapsulant 6 through the opening 61.

Specifically, a surrounding lateral surface of the encapsulant 6 in the present embodiment is substantially flush with or coplanar with a surrounding lateral side of the substrate 1, and the encapsulant 6 in the present embodiment is a molding compound, but the present disclosure is not limited thereto. For example, in other embodiments of the present disclosure not shown in the drawings, the encapsulant 6 can be a liquid compound according to practical requirements.

In summary, in the sensor package structure 100 provided by the present embodiment, the sensing layer 4 is enclosed in the carrier 3 and the cap 5, and then the encapsulant 6 is formed to encapsulate the carrier 3 and the cap 5 for establishing a dual-package configuration, thereby effectively preventing the sensing layer 4 from being affected by an external environment.

Moreover, since the sensing layer 4 of the sensor package structure 100 provided by the present embodiment is enclosed in the carrier 3 and the cap 5, the sensing layer 4 can be effectively isolated from the external environment, thereby reducing a heat conduction effect that may possibly affect the hot junctions 41 and increasing the detection accuracy of the sensor package structure 100.

In addition, in the sensor package structure 100 provided by the present embodiment, the sensing layer 4 can be in cooperation with the internal structures of the carrier 3 and the cap 5 for reducing heat radiation and convection generated from the hot junctions 41 to affect the cold junctions 42, thereby effectively increasing the detection accuracy of the sensor package structure 100.

### Second Embodiment

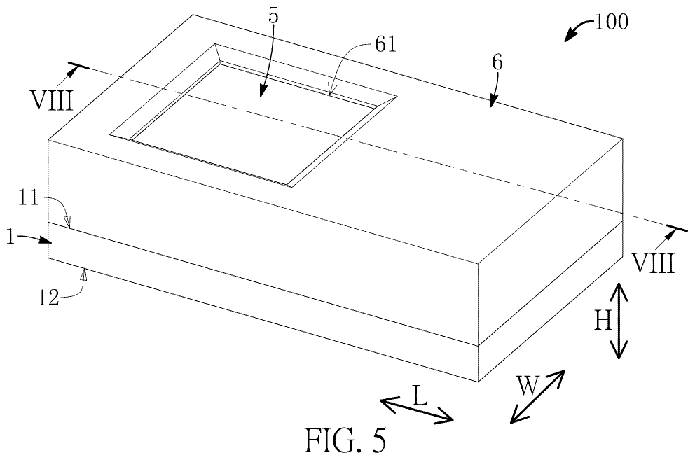

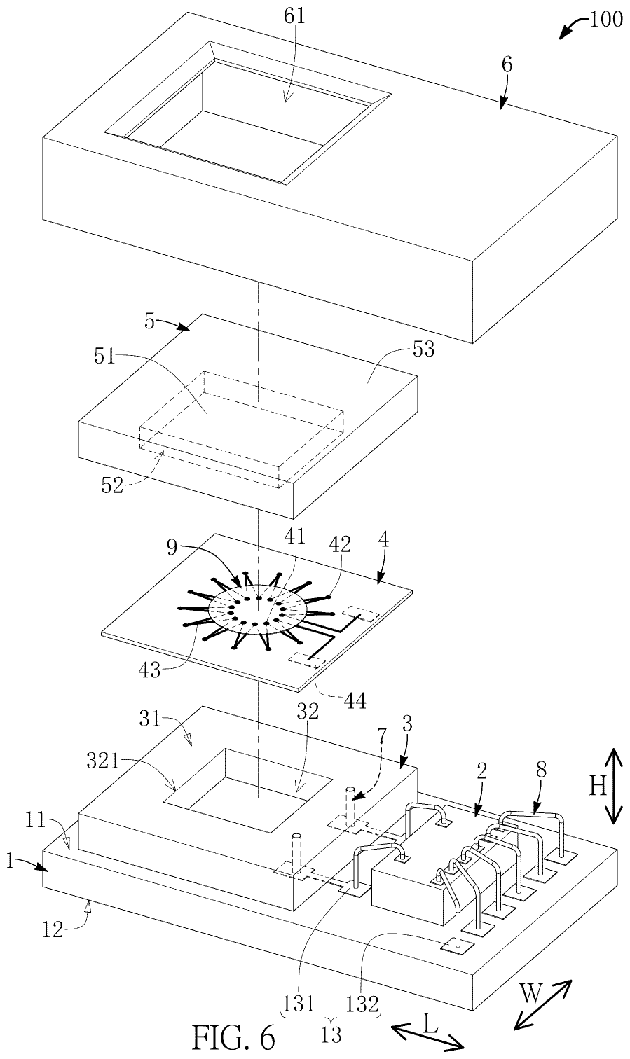

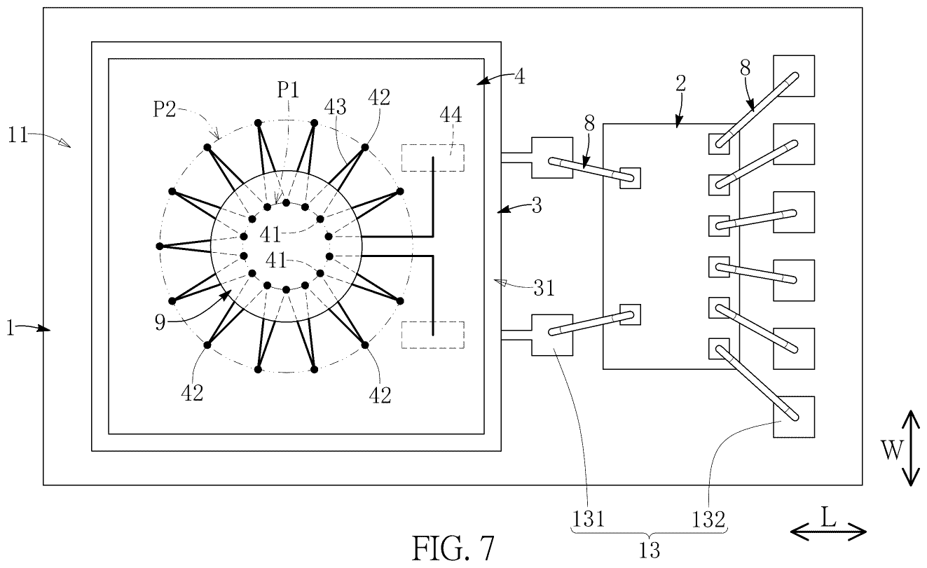

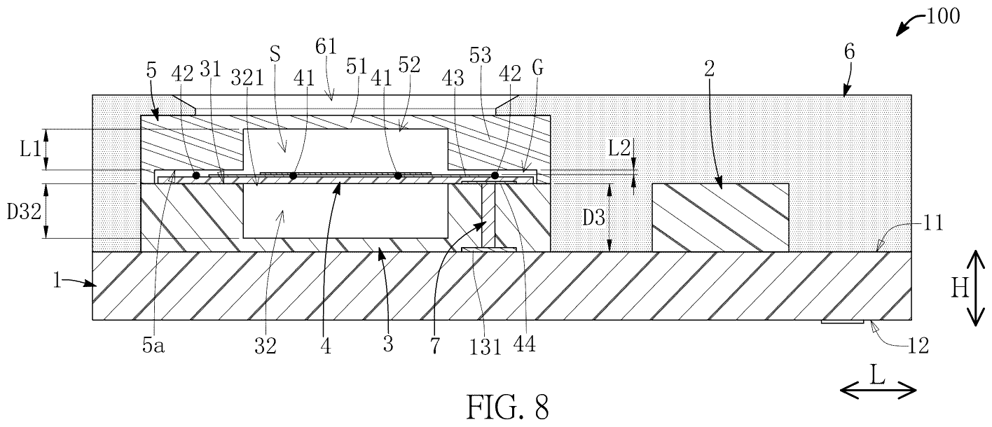

Referring to FIG. 5 to FIG. 8, a second embodiment of the present disclosure, which is similar to the first embodiment of the present disclosure, is provided. For the sake of brevity, descriptions of the same components in the first and second embodiments of the present disclosure will be omitted herein, and the following description only discloses different features (e.g., the sensing layer 5) between the first and second embodiments.

In the present embodiment, an opening 321 of the first slot 32 is entirely covered or shielded by the sensing layer 4. The sensing layer 4 includes a plurality of hot junctions 41 spaced apart from each other, a plurality of cold junctions 42 spaced apart from each other, a thermopile circuit 43 that connects the hot junctions 41 and the cold junctions 42, and an absorption film 9 that covers (or is stacked on) the hot junctions 41, but the present disclosure is not limited thereto. For example, in other embodiments of the present disclosure not shown in the drawings, the absorption film 9 can be omitted or can be replaced by other components according to practical requirements.

Moreover, the hot junctions 41 provided by the present embodiment are in a circular arrangement, the cold junctions 42 are also in a circular arrangement that surrounds at an outer side of the hot junctions 41. A central point of the circular arrangement of the hot junctions 41 is overlapped with a central point of the circular arrangement of the cold junctions 42.

In addition, the thermopile circuit 43 has two connection pads 44 respectively connected to two of the hot junctions 41 that are arranged on ends (or two end segments) of the thermopile circuit 43. The sensing layer 4 is configured to sense light in a predetermined wavelength, and the absorption film 9 is configured to absorb the light for increasing sensitivity of the detection of the sensor package structure 100.

### Third Embodiment

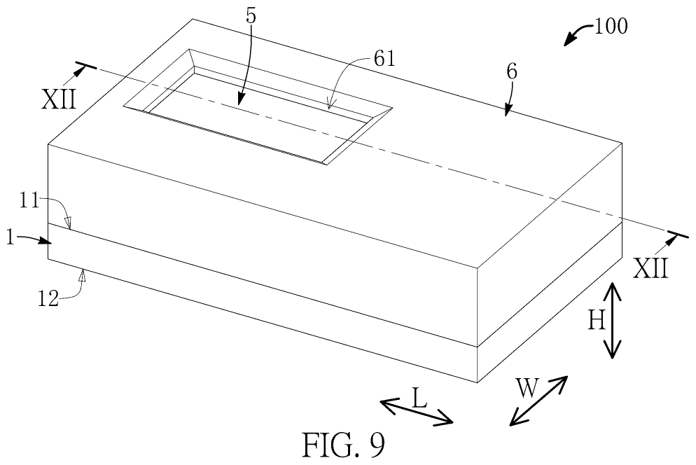

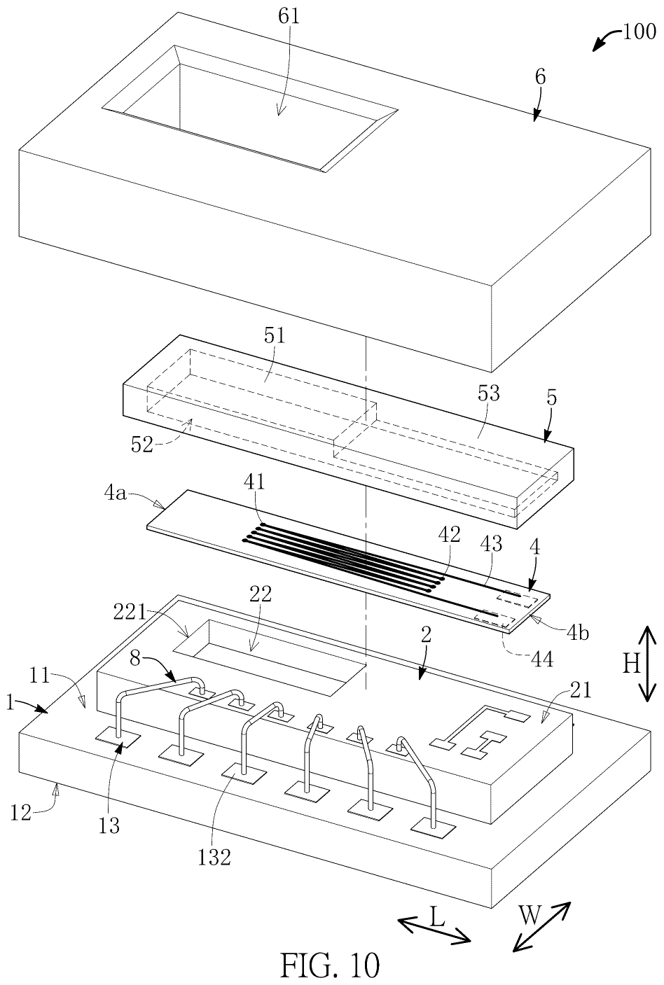

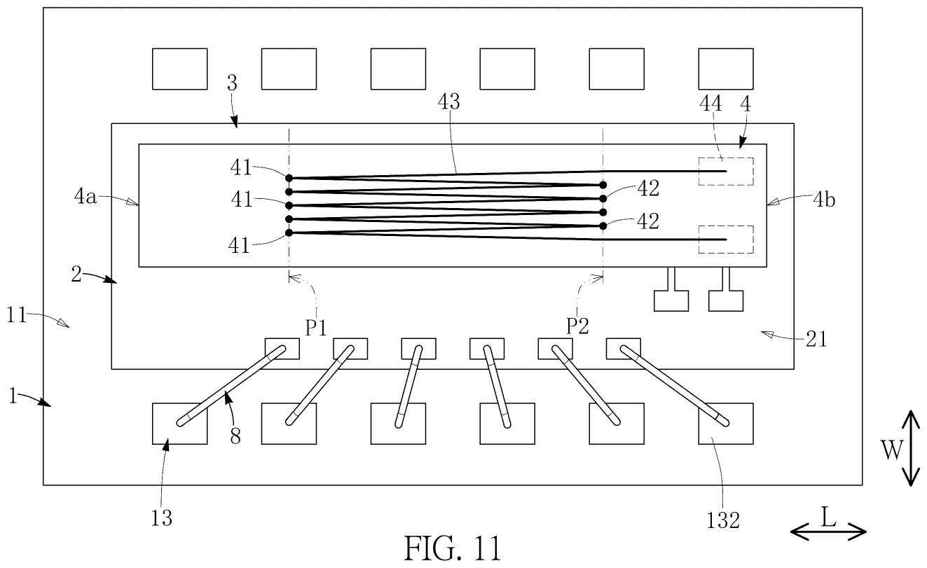

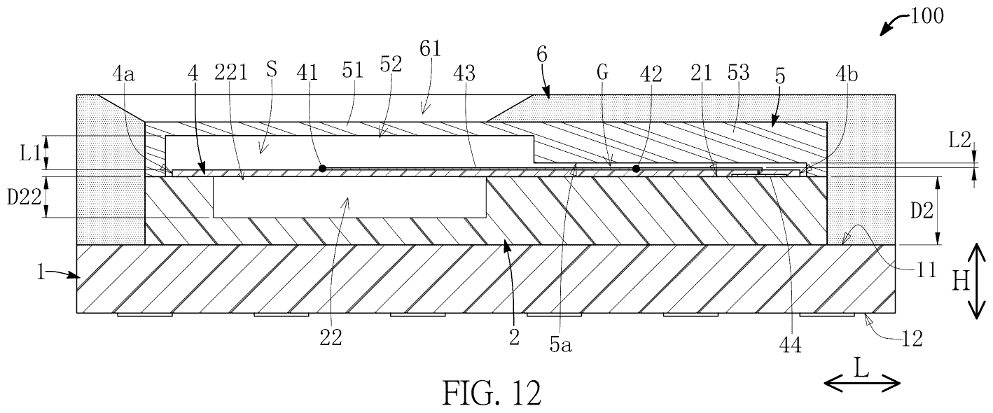

Referring to FIG. 9 to FIG. 12, a third embodiment of the present disclosure, which is similar to the first embodiment of the present disclosure, is provided. For the sake of brevity, descriptions of the same components in the first and third embodiments of the present disclosure will be omitted herein, and the following description only discloses different features between the first and third embodiments.

In the present embodiment, the sensor package structure 100 includes a substrate 1, a processor 2 disposed on the substrate 1, a sensing layer 4 disposed on the processor 2, a cap 5 disposed on the processor 2, and an encapsulant 6 that is formed on the substrate 1. The processor 2 in the present embodiment substantially has the functions of the carrier 3 and the processor 2 provided by the first embodiment, and the following description further describes the structure of the processor 2 of the present embodiment.

In the present embodiment, the processor 2 is an ASIC chip, and the processor 2 has a carrying surface 21 and a first slot 22 that is recessed in the carrying surface 21. The first slot 22 preferably does not penetrate through the processor 2. For example, a depth D22 of the first slot 22 can be within a range from 50% to 90% of a thickness D2 of the processor 2, but the present disclosure is not limited thereto.

In addition, the structure and connection relationship of the substrate 1, the sensing layer 4, the cap 5, and the encapsulant 6 provided by the present embodiment are substantially identical to those of the first embodiment, and can be referred to in the corresponding descriptions in the first embodiment. In other words, the following description of the present embodiment mainly describes the connection relationship of the processor 2 with respect to the substrate 1, the sensing layer 4, the cap 5, and the encapsulant 6.

In the present embodiment, the circuit layer 13 of the substrate 1 only has the external circuits 132 and does not have the connection circuit 131. Moreover, the processor 2 is disposed on the first surface 11 of the substrate 1 and is electrically coupled to the circuit layer 13. The processor 2 is electrically coupled to the external circuits 132 in a wire-bonding manner through a plurality of metal wires 8, but the present disclosure is not limited thereto. For example, in other embodiments of the present disclosure not shown in the drawings, the processor 2 can be electrically coupled to the circuit layer 13 in a flip-chip manner according to practical requirements.

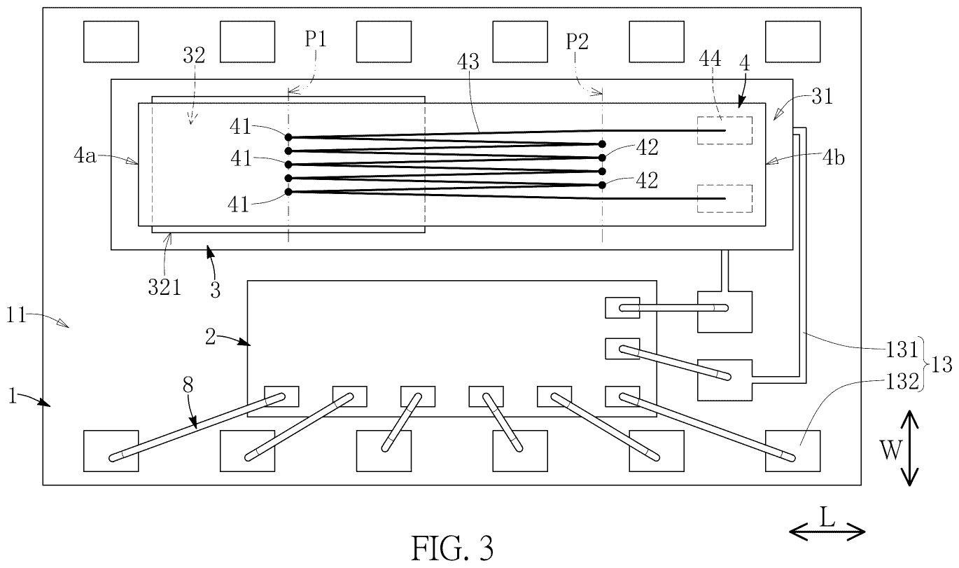

The sensing layer 4 is disposed on the carrying surface 21 of the processor 2 and a contour of the sensing layer 4 does not protrude from the carrying surface 21, and the sensing layer 4 is located at one side of the metal wires 8. An opening 221 of the first slot 22 can be entirely covered or shielded by the sensing layer 4, the hot junctions 41 are located above the first slot 22 of the processor 2, and the cold junctions 42 are disposed on the carrying surface 21 of the processor 2. It should be noted that since the sensing layer 4 in the present embodiment has a thinner thickness, a peripheral portion of the sensing layer 4 can be entirely fixed for minimizing a warpage, thereby preventing the sensing layer 4 from falling into the first slot 22. In other words, when the sensing layer 4 has a larger thickness, the peripheral portion of the sensing layer 4 is partially fixed (e.g., two opposite sides of the peripheral portion of the sensing layer 4 are fixed as shown in FIG. 3), and the sensing layer 4 does not have a warpage issue.

Moreover, the sensing layer 4 in the present embodiment is connected to a corresponding circuit (e.g., two bonding pads) of the processor 2 in a flip-chip manner through the two connection pads 44 thereof, such that the sensing layer 4 is electrically coupled to the processor 2, but the present disclosure is not limited thereto.

The cap 5 is disposed on the carrying surface 21 of the processor 2 to jointly define (or form) an enclosed space S receiving the sensing layer 4 therein. In the present embodiment, a peripheral portion of a bottom of the cap 5 is gaplessly connected to the carrying surface 21 of the processor 2, and the cap 5 is not in contact with the sensing layer 4 and the metal wires 8 that connect the processor 2 and the substrate 1, but the present disclosure is not limited thereto. For example, in other embodiments of the present disclosure not shown in the drawings, the cap 5 can only cover or shield a sensing region defined by the hot junctions 41 and the cold junctions 42 of the sensing layer 4; in other words, the cap 5 is in contact with an outer region (or a non-sensing region) of the sensing layer 4; or, the cap 5 can only cover or shield a sensing region defined by the cold junctions 42 of the sensing layer 4, thereby reducing heat energy being directly transmitted to the cold junctions 42 and preventing a temperature detection of each of the cold junctions 42 from being affected by the hot junctions 41. Accordingly, a significant temperature difference between the cold junctions 42 and the hot junctions 41 can be maintained for increasing detection accuracy of the sensor package structure 100.

The encapsulant 6 is formed on the first surface 11 of the substrate 1. The processor 2, the cap 5, and the metal wires 8 are embedded in the encapsulant 6, and at least part of the light-filtering portion 51 of the cap 5 is exposed from the encapsulant 6. In other words, the encapsulant 6 has an opening 61, and the light-filtering portion 51 is exposed from the encapsulant 6 through the opening 61.

### Beneficial Effects of the Embodiments

In conclusion, in the sensor package structure provided by the present disclosure, the sensing layer is enclosed in the carrier and the cap (or the sensing layer is enclosed in the processor and the cap), and then the encapsulant is formed for establishing a dual-package configuration, thereby effectively preventing the sensing layer from being affected by an external environment.

Moreover, since the sensing layer of the sensor package structure provided by the present disclosure is enclosed in the carrier and the cap (or is enclosed in the processor and the cap), the sensing layer can be effectively isolated from the external environment, thereby reducing a heat conduction effect that may possibly affect the hot junctions and increasing the detection accuracy of the sensor package structure.

In addition, in the sensor package structure provided by the present disclosure, the sensing layer can be in cooperation with the internal structures of the carrier and the cap (or the internal structures of the processor and the cap) for reducing heat radiation and convection generated from the hot junctions to affect the cold junctions, thereby effectively increasing the detection accuracy of the sensor package structure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate;
a carrier disposed on the substrate, wherein the carrier has a carrying surface and a first slot that is recessed in the carrying surface;
a sensing layer disposed on the carrying surface of the carrier and configured to sense light in a predetermined wavelength, wherein the sensing layer has a plurality of hot junctions spaced apart from each other and a plurality of cold junctions that are spaced apart from each other, and wherein the hot junctions are located above the first slot, and the cold junctions are located above the carrying surface;
a cap that is disposed on the carrier to jointly define an enclosed space receiving the sensing layer therein; and
an encapsulant formed on the substrate, wherein the carrier and the cap are embedded in the encapsulant, and at least part of the cap corresponding in position to the hot junctions is exposed from the encapsulant.

2. The sensor package structure according to claim 1, wherein the substrate includes a circuit layer, the sensor package structure further includes at least one conductive pillar that is embedded in the carrier and that is connected to the circuit layer and the sensing layer.

3. The sensor package structure according to claim 1, wherein an inner surface of the cap is arranged adjacent to the cold junctions and is spaced apart from the cold junctions by a distance that is within a range from 50 μm to 200 μm.

4. The sensor package structure according to claim 1, wherein the cap has:
a light-filtering portion arranged above the hot junctions and configured to allow the light to pass therethrough; and
a second slot recessed from a portion of an inner surface of the cap adjacent to the hot junctions to the light-filtering portion.

5. The sensor package structure according to claim 1, further comprising a processor disposed on the substrate and spaced apart from the carrier, wherein the processor is electrically coupled to the sensing layer and is embedded in the encapsulant.

6. The sensor package structure according to claim 1, wherein the sensing layer includes a thermopile circuit that connects the hot junctions and the cold junctions, and wherein, along the thermopile circuit, any one of the hot junctions is located between two of the cold junctions.

7. The sensor package structure according to claim 6, wherein the sensing layer is elongated and has a first end and a second end that is opposite to the first end along a longitudinal direction thereof, and wherein the hot junctions are arranged adjacent to the first end of the sensing layer, and the cold junctions are arranged adjacent to the second end of the sensing layer.

8. The sensor package structure according to claim 7, wherein the thermopile circuit has two connection pads respectively connected to two of the hot junctions that are arranged on ends of the thermopile circuit, wherein the substrate has a circuit layer, and the sensor package structure further includes two conductive pillars embedded in the carrier, and wherein the two conductive pillars are connected to the circuit layer, and are respectively connected to the two connection pads.

9. The sensor package structure according to claim 6, wherein the hot junctions are in a circular arrangement, and the cold junctions are in a circular arrangement and surround the hot junctions.

10. The sensor package structure according to claim 9, wherein a center point of the circular arrangement of the hot junctions is overlapped with a center point of the circular arrangement of the cold junctions.

11. The sensor package structure according to claim 9, wherein the sensing layer includes an absorption film that covers the hot junctions and that is configured to absorb the light.

12. The sensor package structure according to claim 9, wherein the thermopile circuit has two connection pads respectively connected to two of the hot junctions that are arranged on ends of the thermopile circuit, wherein the substrate has a circuit layer, and the sensor package structure further includes two conductive pillars embedded in the carrier, and wherein the two conductive pillars are connected to the circuit layer, and are respectively connected to the two connection pads.

13. The sensor package structure according to claim 1, wherein the light sensed by the sensing layer is infrared radiation, and the cap is configured to not allow visible light to pass therethrough.

14. The sensor package structure according to claim 13, wherein the carrier and the cap are configured to allow the infrared radiation to pass therethrough, and the transmittance of the infrared radiation of the carrier is less than or equal to the transmittance of the infrared radiation of the cap.

15. The sensor package structure according to claim 1, wherein the carrier and the cap are made of silicon.

16. A sensor package structure, comprising:
a substrate;
a processor disposed on the substrate, wherein the processor has a carrying surface and a first slot that is recessed in the carrying surface;
a sensing layer configured to sense light in a predetermined wavelength, wherein the sensing layer is disposed on the carrying surface of the processor and is electrically coupled to the processor, wherein the sensing layer has a plurality of hot junctions spaced apart from each other and a plurality of cold junctions that are spaced apart from each other, and wherein the hot junctions are located above the first slot, and the cold junctions are located above the carrying surface;
a cap that is disposed on the carrier to jointly define an enclosed space receiving the sensing layer therein, wherein the cap has:
a light-filtering portion arranged above the hot junctions and configured to allow the light to pass therethrough; and
a second slot recessed from a portion of an inner surface of the cap adjacent to the hot junctions to the light-filtering portion; and
an encapsulant formed on the substrate, wherein the processor and the cap are embedded in the encapsulant, and at least part of an outer surface of the light-filtering portion of the cap is exposed from the encapsulant.

17. The sensor package structure according to claim 16, wherein the inner surface of the cap is arranged adjacent to the cold junctions and is spaced apart from the cold junctions by a distance that is within a range from 50 μm to 200 μm.

18. The sensor package structure according to claim 16, wherein the sensing layer is elongated and has a first end and a second end that is opposite to the first end along a longitudinal direction thereof, and wherein the hot junctions are arranged along a first layout path perpendicular to the longitudinal direction and is arranged adjacent to the first end of the sensing layer, and the cold junctions are arranged along a second layout path parallel to the first layout path and are arranged adjacent to the second end of the sensing layer.

19. The sensor package structure according to claim 17, wherein the sensing layer includes a thermopile circuit that connects the hot junctions and the cold junctions, wherein the thermopile circuit has two connection pads respectively connected to two of the hot junctions that are arranged on ends of the thermopile circuit, and wherein, along the thermopile circuit, any one of the hot junctions is located between two of the cold junctions.

20. The sensor package structure according to claim 16, wherein the light sensed by the sensing layer is infrared radiation, and the light-filtering portion is configured to not allow visible light to pass therethrough.
